(19) United States
(12) Patent Application Publication
(10) Pub. No.: US 2019/0233968 A1
(43) Pub. Date: Aug. 1, 2019

(54) GAS INJECTOR FOR CHEMICAL VAPOR DEPOSITION SYSTEM

(71) Applicant: HERMES-EPITEK CORPORATION, Taipei City (TW)

(72) Inventors: Po-Ching Lu, Taipei City (TW); Kuan-Ning Huang, New Taipei City (TW)

(21) Appl. No.: 16/254,385

(22) Filed: Jan. 22, 2019

(30) Foreign Application Priority Data
Jan. 30, 2018 (TW) 107103158

(51) Int. Cl. C30B 25/14; C30B 25/16

(52) U.S. Cl. CPC C30B 25/14; C30B 25/165

(57) ABSTRACT

A gas injector for a chemical vapor deposition (CVD) system is provided with one or more gas distributing layers. Each gas distributing layer comprises a central portion, a plurality of stream guides, and a plurality of gas channels. A gas distributer is placed within the central portion. Each stream guide has a first end, a middle portion, and a second end, where the middle portion is arranged between the first end and the second end, the first end is arranged near the central portion, and the second end is arranged near the peripheral of the gas distributing layer. Each gas channel is formed and interposed between two of the plurality of stream guides and allows transportation of gas. The width of each stream guide is gradually increased from the first end to the middle portion and is gradually decreased from the middle portion to the second end.

### CROSS-REFERENCE TO RELATED APPLICATIONS

The entire contents of Taiwan Patent Application No. 107103158, filed on Jan. 30, 2018, from which this application claims priority, are expressly incorporated herein by reference.

### BACKGROUND OF THE INVENTION

### 1. Field of the Invention

The present invention relates to a deposition system and more particularly relates to a gas injector applied in chemical vapor deposition (CVD) system.

### 2. Description of Related Art

Metal-Organic Chemical Vapor Deposition (MOCVD) is a process to deposit a film on a surface of a semiconductor wafer or other substrates. MOCVD employs a carrier gas to carry gaseous reactants or precursors into a reactor chamber loaded with wafers. A susceptor bears the wafers and uses a heating mechanism to heat the wafers and the gases approaching the substrates. As the temperature of the approaching gases is raised, one or more chemical reactions are triggered. The chemical reactions convert gaseous reactants into solid products to be deposited on the surfaces of the wafers.

The quality and yield rate of thin films formed by MOCVD depend on process conditions such as the stability and uniformity of gas flow, temperature control, and gas control of the reactor chamber. Each of the above conditions will strongly affect the quality and uniformity of the deposited thin films.

In addition, the carrier gas such as hydrogen or nitrogen gas carries the gaseous reactants to the surface of the wafer and the reactants are converted to products by reactions. The reaction efficiency are affected by various factors including activity of reactants, design of the reactor chamber, pressure and flow rate of the gases, and process control parameters of the deposition. For a MOCVD system, it is an important issue to improve the reaction efficiency so as to promote the yield rate of the deposition.

In a MOCVD system, typically an injector is employed to feed carrier gas and reactant gases, such us Group III elements and group V elements, into a planetary MOCVD so as to form group III-V compound thin-film on the wafer. FIG. 1 is a side view showing a conventional triple injector 1 used in a MOCVD system. Referring to FIG. 1, the triple injector 1 mainly includes an upper channel 12A, a middle channel 12B, and a lower channel 12C arranged at a high level, a middle level, and a low level, respectively. Hydrogen or nitrogen gas is used as the carrier gas for the three channels. In detail, group V gases, e.g., ammonia (NH₃), are injected through the upper channel 12A and the lower channel 12C, and group III gases, e.g., Trimethylgallium (TMGa) or trimethyl aluminum (TMAl), are injected through the middle channel 12B. Then group V gases meets group III gases at the region on which the wafer 14 is placed, and the group III gases reacts with group V gases to form an III-V compound thin-film on the surface of wafer 14.

Referring to FIG. 1, because various gases are distributed through the upper channel 12A, the middle channel 12B, and the lower channel 12C with different heights, the distributed gas from each channel needs a period of time for mixing with other gases when it diffuses vertically and transversely, and the reaction is initiated until the mixing is completed. The inefficient diffusion of gases will result in the increase of time of the depositing process.

### SUMMARY OF THE INVENTION

In one general aspect, the present invention relates to a chemical deposition system and more particularly, relates to a gas injector applied in a chemical vapor deposition (CVD) system to improve the diffusion efficiency of the gases.

According to an embodiment of the present invention, a gas injector for a chemical vapor deposition (CVD) system is provided with one or more gas distributing layers. Each gas distributing layer comprises a central portion, a plurality of stream guides, and a plurality of gas channels. A gas distributer is placed within the central portion. Each stream guide has a first end, a middle portion, and a second end, wherein the middle portion is arranged between the first end and the second end, the first end is arranged near the central portion, and the second end is arranged near the peripheral of the gas distributing layer. Each gas channel is formed and interposed between two of the plurality of stream guides and allows transportation of gas provided by the gas distributer. The width of each stream guide is gradually increased from the first end to the middle portion and is gradually decreased from the middle portion to the second end.

According to another embodiment of the present invention, a gas injector for a chemical vapor deposition (CVD) system is provided with one or more gas distributing layers. Each gas distributing layer comprises a central portion, a plurality of stream guides, and a plurality of gas channels. A gas distributer is placed within the central portion. Each stream guide has a first end, a middle portion, and a second end, wherein the middle portion is arranged between the first end and the second end, the first end is arranged near the central portion, and the second end is arranged near the peripheral of the gas distributing layer. Each gas channel is formed and interposed between two of the plurality of stream guides and allows transportation of gas provided by the gas distributer. The width of the middle portion is greater than the width of the first end and the width of the second end.

In an embodiment of this invention, laminar flow occurs at the combination of two gases from two gas channels adjacent to each other.

In an embodiment of this invention, each stream guide has a darts-shaped configuration.

In an embodiment of this invention, the width of the second end of each stream guide is zero.

In an embodiment of this invention, a distance is between the second end of each stream guide and the peripheral of the gas distributing layer.

In an embodiment of this invention, a configuration between the first end and the middle portion of each stream guide is fan-shaped.

In an embodiment of this invention, a configuration between the middle portion the second end is triangle-shaped.

Accordingly, embodiments of the present invention provide a gas injector in which the various reactant gases are transversely injected into the reactor on a same plane. Both the diffusion time of the gases and the volume of the gas injector can be decreased. In addition, the gas flow distributed by the gas injector is a laminar flow with no disruption between layers. Consequently, the uniformity and yield rate of the deposited thin films are promoted.

### BRIEF DESCRIPTION OF THE DRAWINGS

FIG. 1 is a side view showing a conventional triple injector for a Metal-Organic Chemical Vapor Deposition (MOCVD) reactor.

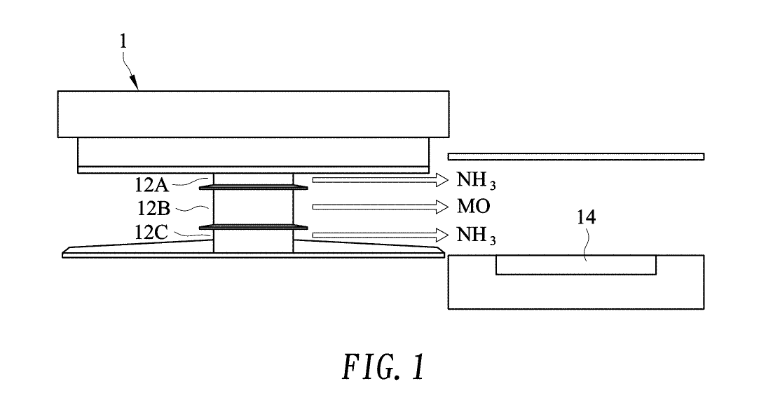

FIG. 2 is a perspective view showing a gas injector used in a chemical vapor deposition system in accordance with an embodiment of the present invention.

FIG. 3 is a simulation result showing the gas flow distributed from the gas injector of FIG. 2, wherein the gases are distributed with a high flow rate.

FIG. 4 is a simulation result showing the gas flow distributed from the gas injector of FIG. 2, wherein the gases are distributed with a low flow rate.

FIG. 5 is a perspective view showing a gas injector used in a chemical vapor deposition system in accordance with a preferred embodiment of the present invention.

FIG. 6 is a top view showing a gas injector used in a chemical vapor deposition system in accordance with the preferred embodiment of the present invention.

FIG. 7 is a simulation result showing the gas flow distributed from the gas injector of FIGS. 5 and 6, wherein the gases are distributed with a high flow rate.

FIG. 8 is a simulation result showing the gas flow distributed from the gas injector of FIGS. 5 and 6, wherein the gases are distributed with a low flow rate.

### DETAILED DESCRIPTION OF THE PREFERRED EMBODIMENT

Reference will now be made in detail to those specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention. While drawings are illustrated in detail, it is appreciated that the quantity of the disclosed components, for example, gas distributing layer, gas channel, etc., may be greater or less than that disclosed, except where expressly restricting the amount of the components. In addition, some of the disclosed components may not be drawn in scale, and some portion of the disclosed components may be magnified or simplified to stress the features of the invention. Wherever possible, the same or similar reference numbers are used in drawings and the description to refer to the same or like parts.

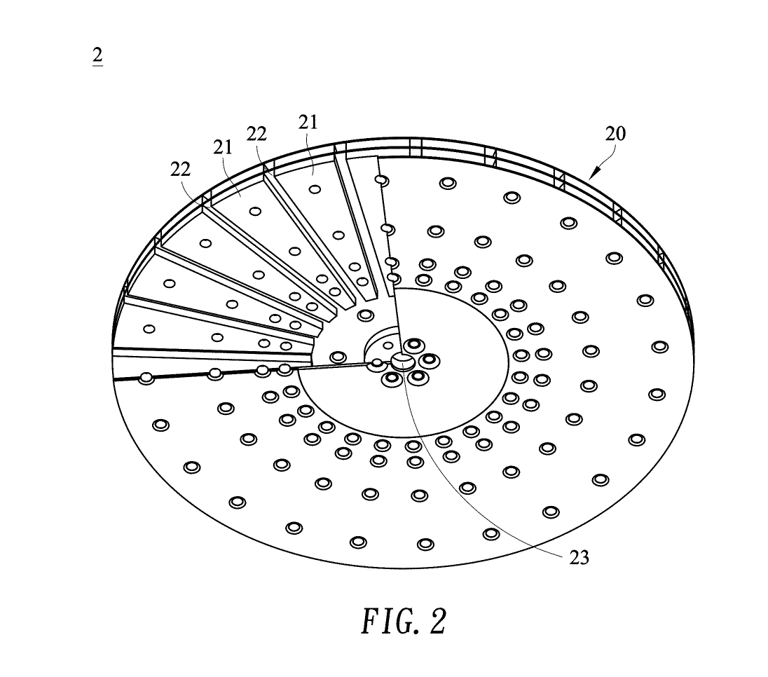

Referring to FIG. 2, a perspective view of a gas injector 2 for a chemical vapor deposition system is provided according to an embodiment of the present invention. Preferably, the chemical vapor deposition system is a Metal-Organic Chemical Vapor Deposition (MOCVD) system; however, it could be other chemical deposition systems in another embodiment of the present invention. For illustration, some components of the gas injector 2 are cut or omitted. Referring to FIG. 2, the gas injector 2 includes one or more gas distributing layers 20, and each gas distributing layer 20 has a single-layer configuration to transversely distribute different gases through a same plane. In this embodiment, the number of the gas distributing layers 20 is two, but it should be not limited and could be other numbers in another embodiment of the present invention.

Referring to FIG. 2, each gas distributing layer 20 comprises a plurality of spaced apart stream guides 21 and a plurality of gas channels 22, where each gas channel 22 is formed and interposed between two of the plurality of stream guides 21. Each of the stream guide 21 and gas channel 22 is radially outwardly extended from the center toward the periphery of the gas distributing layer 20. Each gas channel 22 includes a gas inlet in the center of the gas distributing layer 20 and a gas outlet in the periphery of the gas distributing layer 20.

Referring to FIG. 2, a central portion 23 of the gas distributing layer 20 is used as a gas supplying source to place a gas distributing device (not shown) for supplying various reactant gases, such as a first gas, a second gas, and a third gas. The gas distributing device can distribute a selected reactant gas, e.g., the first gas, the second gas, or the third gas, to a corresponded specific gas channel

The gas distributing device can be any suitable gas distributing device used in the art, and the detail of which is omitted for simplicity. In an embodiment of the present invention, a gas distributing device described in Taiwan Patent Application, application no. 105131760, entitled “Gas Distributing Injector Applied in MOCVD Reactor,” is employed by an embodiment of the present invention to distribute various gases, and the entire contents of the above-mentioned application are incorporated herein by reference.

Referring to FIG. 2, each gas channel 22 allows transportation of a gas provided by the gas distributing device, where the gas is fed from the gas inlet at the center of the gas distributing layer 101 and is sprayed out from the gas outlet at the peripheral of the gas distributing layer 102.

In addition, when various gases flow into the gas injector 2, the gas distributing device distributes a selected reactant gas, e.g., the first gas, the second gas, or the third gas, to the corresponded specific gas channels. Further, the flow rate for the gas channels corresponding to different gases can be respectively adjusted. In an embodiment of the present invention, the gas injector 2 includes a top gas inlet, a middle gas inlet, and a bottom gas inlet (not shown), and the gas distributing device supplies various gases to the gas channels 22 through the top, middle, and bottom gas.

Referring to FIG. 2, because each gas channel 22 does not communicate with other gas channels 22, the various gases are not mixed with others within the gas distributing layer 20. After the various gases are sprayed into the reactor from the periphery of the gas distributing layer 20 on a same plane, the sprayed gases are transversely diffused to meet other gases, so that the reactants react to form a thin film on the surface of the wafer. Instead of conventional triple gas injector, the embodiment of the present invention provides a gas injector having a single layer configuration, wherein the gases are sprayed through a same plane so that the vertical diffusion is unnecessary and only the transverse diffusion is needed and therefore the depositing time can be significantly reduced.

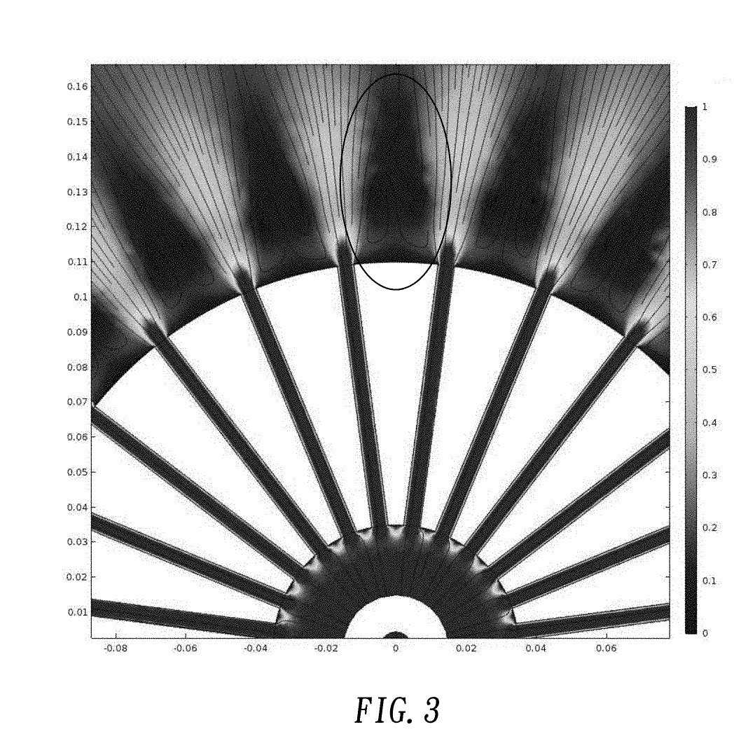

In practical, however, the gas injector 2 of FIG. 2 has some disadvantages needed to be improved. FIG. 3 is a result showing a first simulation of the gas injector 2 of FIG. 2, where both the x and y coordinate denote length dimension. Referring to FIG. 3, the flow rate within a top, middle, and bottom gas inlet of gas injector are 30 slm, 15 slm, and 15 slm (standard litre per minute), respectively. As shown in the circle of FIG. 3, turbulence occurs at the combination of the gas sprayed from one gas channel and the gas sprayed from the neighbor gas channel with the above conditions.

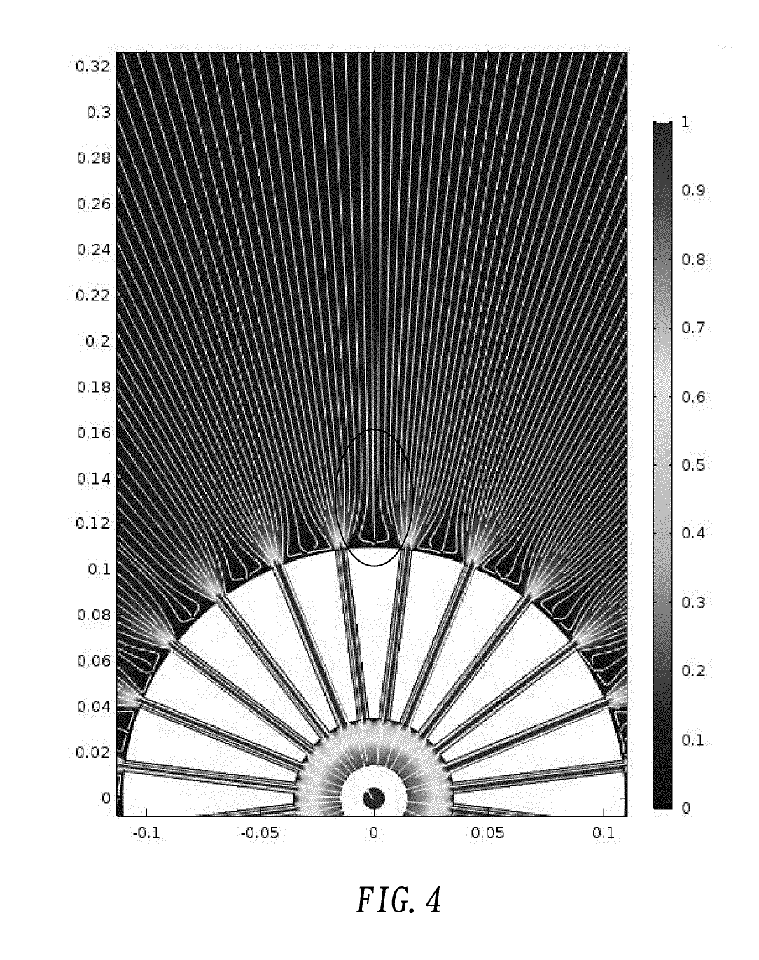

FIG. 4 is a result showing a second simulation of the gas injector 2 of FIG. 2. Referring to FIG. 4, the flow rate within the top, middle, and bottom gas inlet of gas injector are 7 slm, 9 slm, and 9 slm, respectively. As shown in the circle of FIG. 4, turbulence occurs at the combination of the gas sprayed from one gas channel and the gas sprayed from the neighbor gas channel with the above conditions.

Regardless of high or low flow rate, the results of FIGS. 3 and 4 show that turbulence occurs at the place of the combination of two gases from two gas channels adjacent to each other. According to fluid mechanics, as the Reynolds number is large, the inertial forces of the fluid dominate the viscous forces, resulting in unstable flow and turbulence. The turbulences of the gas flow within the reactor probably cause the reactions incomplete and by products may be generated, such that the defects of thin film are increased and the uniformity of the deposition is decreased.

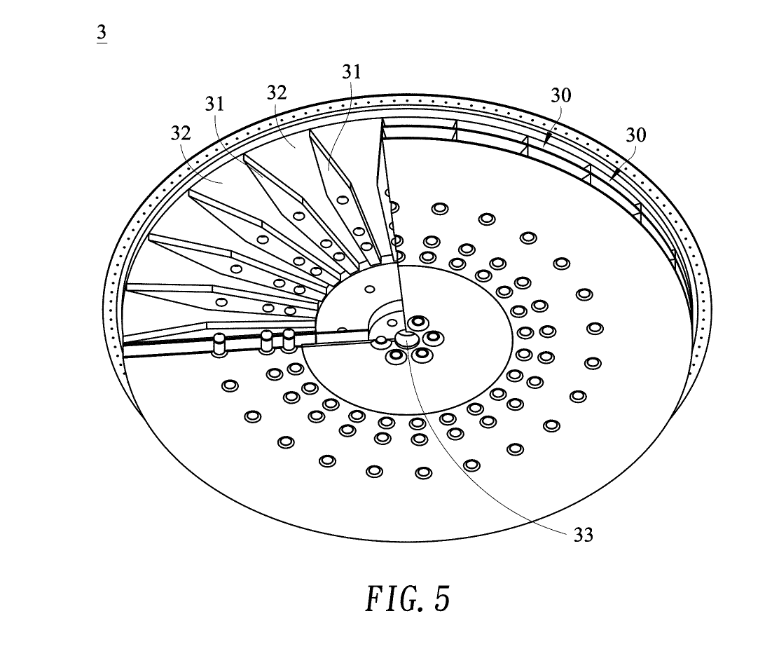

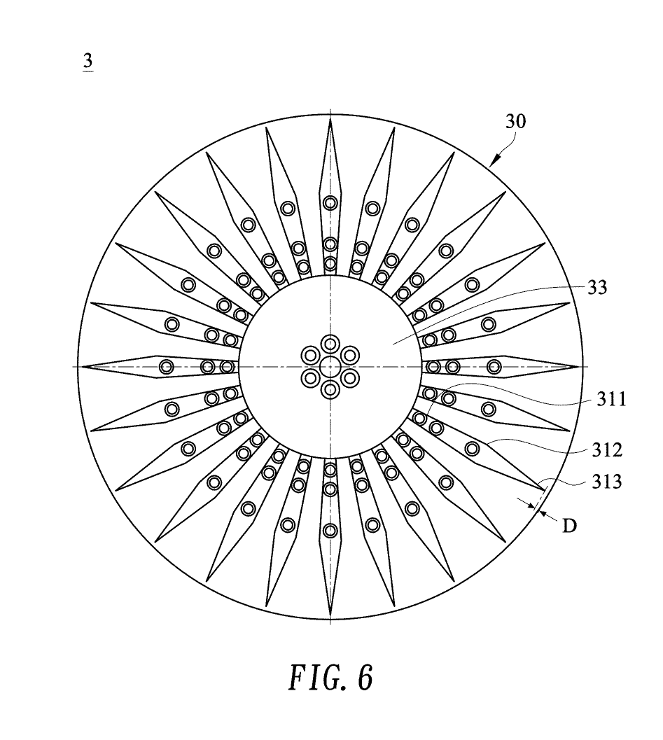

To overcome the disadvantages of the gas injector of FIG. 2, the present invention provides another gas injector used in a CVD system, such as a MOCVD system. FIG. 5 is a perspective view and FIG. 6 is a top view to show a gas injector 3 for a chemical vapor deposition system in accordance with a preferred embodiment of the present invention.

Preferably, the chemical vapor deposition system is a Metal-Organic Chemical Vapor Deposition (MOCVD) system; however, it could be other chemical deposition systems in another embodiment of the present invention. For illustration purpose, some components of the gas injector 3 are cut or omitted. Referring to FIGS. 5 and 6, the gas injector 3 includes one or more gas distributing layers 30, and each gas distributing layer 30 has a single-layer configuration to transversely distribute different gases through a same plane.

Referring to FIGS. 5 and 6, each gas distributing layer 30 comprises a plurality of spaced apart stream guides 31 and a plurality of gas channels 32 on a same plane, where each gas channel 32 is formed and interposed between two of the plurality of stream guides 31. Preferably, the stream guides are evenly spaced, but this is not limited. Each of the stream guide 31 and gas channel 32 is radially outwardly extended from the center toward the periphery of the gas distributing layer 30. Each gas channel 32 includes a gas inlet in the center of the gas distributing layer 30 and a gas outlet in the periphery of the gas distributing layer 30. Referring to FIGS. 5 and 6, a central portion 33 of the gas distributing layer 30 is used as a gas supplying source to place a gas distributing device (not shown) for supplying various reactant gases. The gas distributing device can distribute a selected reactant gas to a corresponded specific gas channel 32.

The difference between the gas distributing layer 20 of FIG. 2 and the gas distributing layer 30 of FIGS. 5-6 are described as follows. Referring to FIG. 2, each stream guide 21 of the gas distributing layer 20 is fan-shaped with a first end and a second end, where the first end is near to the center of the gas distributing layer 20, and the second end is near to the periphery of the gas distributing layer 20. For each stream guide 21, the first end has the shortest width and the second end has the longest width, i.e., the width of the stream guide 21 being gradually increased from the first end to the second end. By contrast, each stream guide 31 of FIGS. 5 and 6 has a darts-shaped or a diamond-shaped configuration. Each stream guide 31 has a first end 311, a second end 313, and a middle portion 312 between the first end 311 and the second 313. The second end 313 is the narrowest place of the stream guide 31, and the middle portion 312 is the widest place of the stream guide 31. The width of each stream guide 31 is gradually increased from the first end 311 to the middle portion 312 and is gradually decreased from the middle portion 312 to the second end 313. In an embodiment of the present invention, the width of the second end 313 of the stream guide 31 is zero, but this is not limited to. Referring to FIG. 6, in an embodiment of the present invention, a distance D is between the second end 313 and the periphery of the gas distributing layer 30. The distance D may be omitted in another embodiment of the present invention. In an embodiment of the present invention, the configuration of each stream guide 31 between the first end 311 and the middle portion 312 is fan-shaped, and the configuration of each steam guide 31 between the middle portion 312 and the second end 313 is triangle-shaped.

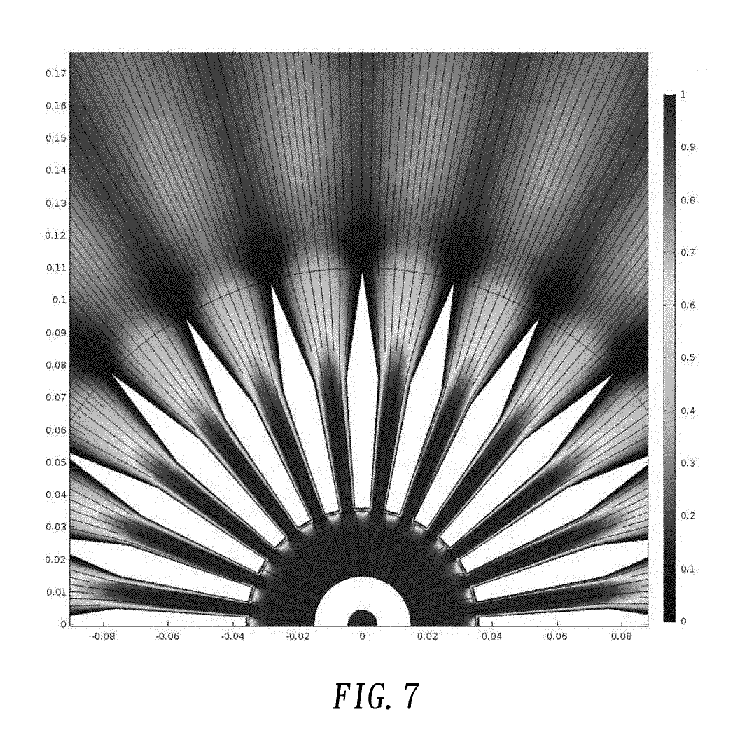

FIG. 7 is a result showing a first simulation of the gas injector 3 of FIGS. 5 and 6, where both the x and y coordinate denote length dimension. Referring to FIG. 7, the flow rate within a top, middle, and bottom gas inlet of gas injector 3 are 30 slm, 15 slm, and 15 slm (standard litre per minute), respectively. As shown in FIG. 7, the gas flow is a Laminar flow without turbulence at the combination of the gas sprayed from one gas channel and the gas sprayed from the neighbor gas channel

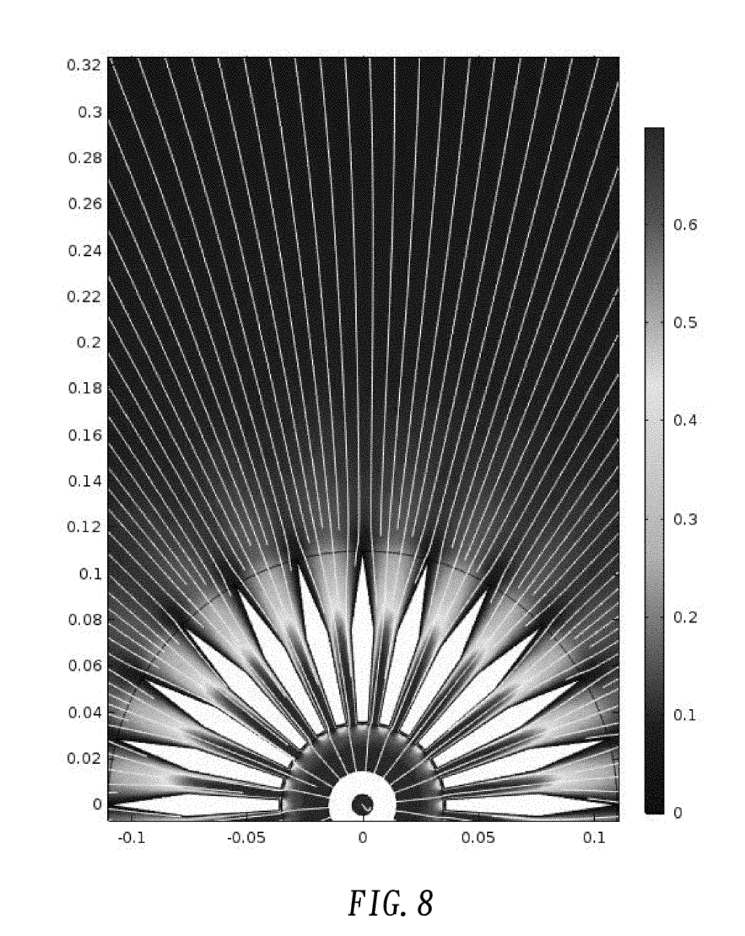

FIG. 8 is a result showing a second simulation of the gas injector 3 of FIGS. 5 and 6. Referring to FIG. 8, the flow rate within the top, middle, and bottom gas inlet of gas injector are 7 slm, 9 slm, and 9 slm, respectively. As shown in FIG. 8, the gas flow is a Laminar flow without turbulence at the combination of the gas sprayed from one gas channel and the gas sprayed from the neighbor gas channel

Regardless of high or low flow rates, the results of FIGS. 7 and 8 show that the gas flow is a Laminar flow without turbulence at the combination of two gases from two gas channels adjacent to each other. According to fluid mechanics, as the Reynolds number is small, the viscous forces of the fluid dominate the inertial forces, resulting in stable laminar flow with no disruption between layers. The laminar flow is necessary within the reactor for completing reactions, reducing defects, and prompting the uniformity of the deposition.

Accordingly, the embodiments of the present invention provide a gas injector in which the various reactant gases are transversely injected into the reactor on a same plane. Both the diffusion time of the gases and the volume of the gas injector can be decreased. In addition, the gas flow distributed by the gas injector is a laminar flow with no disruption between layers. Consequently, the uniformity and yield rate of the deposited thin films are promoted.

The intent accompanying this disclosure is to have each/all embodiments construed in conjunction with the knowledge of one skilled in the art to cover all modifications, variations, combinations, permutations, omissions, substitutions, alternatives, and equivalents of the embodiments, to the extent not mutually exclusive, as may fall within the spirit and scope of the invention. Corresponding or related structure and methods disclosed or referenced herein, and/or in any and all co-pending, abandoned or patented application(s) by any of the named inventor(s) or assignee(s) of this application and invention, are incorporated herein by reference in their entireties, wherein such incorporation includes corresponding or related structure (and modifications thereof) which may be, in whole or in part, (i) operable and/or constructed with, (ii) modified by one skilled in the art to be operable and/or constructed with, and/or (iii) implemented/made/used with or in combination with, any part(s) of the present invention according to this disclosure, that of the application and references cited therein, and the knowledge and judgment of one skilled in the art.

Conditional language, such as, among others, “can,” “could,” “might,” or “may,” unless specifically stated otherwise, or otherwise understood within the context as used, is generally intended to convey that embodiments include, and in other interpretations do not include, certain features, elements and/or steps. Thus, such conditional language is not generally intended to imply that features, elements and/or steps are in any way required for one or more embodiments, or interpretations thereof, or that one or more embodiments necessarily include logic for deciding, with or without user input or prompting, whether these features, elements and/or steps are included or are to be performed in any particular embodiment.

All of the contents of the preceding documents are incorporated herein by reference in their entireties. Although the disclosure herein refers to certain illustrated embodiments, it is to be understood that these embodiments have been presented by way of example rather than limitation. For example, any of the particulars or features set out or referenced herein, or other features, including method steps and techniques, may be used with any other structure(s) and process described or referenced herein, in whole or in part, in any combination or permutation as a non-equivalent, separate, non-interchangeable aspect of this invention. Corresponding or related structure and methods specifically contemplated and disclosed herein as part of this invention, to the extent not mutually inconsistent as will be apparent from the context, this specification, and the knowledge of one skilled in the art, including, modifications thereto, which may be, in whole or in part, (i) operable and/or constructed with, (ii) modified by one skilled in the art to be operable and/or constructed with, and/or (iii) implemented/made/used with or in combination with, any parts of the present invention according to this disclosure, include: (I) any one or more parts of the above disclosed or referenced structure and methods and/or (II) subject matter of any one or more of the inventive concepts set forth herein and parts thereof, in any permutation and/or combination, include the subject matter of any one or more of the mentioned features and aspects, in any permutation and/or combination.

What is claimed is:

1. A gas injector for a chemical vapor deposition system, comprising:
one or more gas distributing layer with each transversely distributing various gases through a same plane and comprising:
a central portion for placing a gas distributer and allowing transportation of gas;
a plurality of stream guides, each stream guide having a first end, a middle portion, and a second end, wherein the middle portion is arranged between the first end and the second end, the first end is arranged near the central portion, and the second end is arranged near a peripheral of the gas distributing layer; and
a plurality of gas channels, each gas channel being interposed between two of the plurality of stream guides and allowing transportation of gas provided by the gas distributer;
wherein the width of each stream guide is gradually increased from the first end to the middle portion and is gradually decreased from the middle portion to the second end.

2. The gas injector as set forth in claim 1, wherein laminar flow occurs at the combination of two gases from two gas channels adjacent to each other.

3. The gas injector as set forth in claim 1, wherein each stream guide has a darts-shaped configuration.

4. The gas injector as set forth in claim 1, wherein the width of the second end of each stream guide is zero.

5. The gas injector as set forth in claim 1, wherein a distance is between the second end of each stream guide and the peripheral of the gas distributing layer.

6. The gas injector as set forth in claim 1, wherein a configuration between the first end and the middle portion of each stream guide is fan-shaped.

7. The gas injector as set forth in claim 1, wherein a configuration between the middle portion the second end is triangle-shaped.

8. A gas injector for a chemical vapor deposition system, comprising:
one or more gas distributing layer with each transversely distributing various gases through a same plane and comprising:
a central portion for placing a gas distributer and allowing transportation of gas;
a plurality of stream guides, each stream guide having a first end, a middle portion, and a second end, wherein the middle portion is arranged between the first end and the second end, the first end is arranged near the central portion, and the second end is arranged near a peripheral of the gas distributing layer; and
a plurality of gas channels, each gas channel being interposed between two of the plurality of stream guides and allowing transportation of gas provided by the gas distributer;
wherein the width of the middle portion is greater than the width of the first end and the width of the second end.

9. The gas injector as set forth in claim 8, wherein the width of each stream guide is gradually increased from the first end to the middle portion and is gradually decreased from the middle portion to the second end.

10. The gas injector as set forth in claim 8, wherein laminar flow occurs at the combination of two gases from two gas channels adjacent to each other.

11. The gas injector as set forth in claim 8, wherein each stream guide has a darts-shaped configuration.

12. The gas injector as set forth in claim 8, wherein the width of the second end of each stream guide is zero.

13. The gas injector as set forth in claim 8, wherein a distance is between the second end of each stream guide and the peripheral of the gas distributing layer.

14. The gas injector as set forth in claim 8, wherein a configuration between the first end and the middle portion of each stream guide is fan-shaped.

15. The gas injector as set forth in claim 8, wherein a configuration between the middle portion the second end is triangle-shaped.
